(19) United States
(12) Patent Application Publication
(10) Pub. No.: US 2019/0211441 A1
(43) Pub. Date: Jul. 11, 2019

(54) STORAGE DEVICE WITH SEALING FUNCTION AND HEATING ASSEMBLY

(71) Applicant: SHENZHEN CHINA STAR OPTOELECTRONICS SEMICONDUCTOR DISPLAY TECHNOLOGY CO., LTD., Shenzhen (CN)

(72) Inventors: Xiaoping QIAO, Shenzhen (CN); Jinchuan LI, Shenzhen (CN)

(21) Appl. No.: 15/957,248

(22) Filed: Apr. 19, 2018

Related U.S. Application Data
(63) Continuation of application No. PCT/CN2018/074094, filed on Jan. 25, 2018.

(30) Foreign Application Priority Data
Jan. 11, 2018 (CN) 201810025635.5

(51) Int. Cl. C23C 14/24

(52) U.S. Cl. CPC C23C 14/243

(57) ABSTRACT

The present disclosure discloses a storage device with a sealing function, including a storage box, a sealing cover, and an elastic member, the storage box is provided with an opening, the sealing cover is rotatably connected to the storage box, the sealing cover is used to seal the opening, the fixing end of the elastic member is connected to the storage box, the free end of the elastic member is configured to connect the sealing cover so that the sealing cover opens from the opening. The present disclosure further discloses a heating assembly, including a crucible and a storage device with a sealing function, wherein the storage device with a sealing function is accommodated in the crucible. The sealing cover is used to seal the opening of the storage box so as to prevent the active material in the storage box from being exposed to the air.

### RELATED APPLICATIONS

This application is a continuation application of PCT Patent Application No. PCT/CN2018/074094, filed Jan. 25, 2018, which claims the priority benefit of Chinese Patent Application No. 201810025635.5, filed Jan. 11, 2018, which is herein incorporated by reference in its entirety.

### FIELD OF THE DISCLOSURE

The present disclosure relates to a panel evaporation process technology, and more particularly to a storage device with a sealing function and a heating assembly.

### BACKGROUND OF THE DISCLOSURE

Organic Light-Emitting Diode (OLEO) has the characteristics of self-luminous, light and thin, and easy to realize flexible display. It is a new generation of display technology with good development prospect. At present, in the OLED panel manufacturing process, the vapor deposition of the OLED material generally adopts the physical vapor deposition method, that is, the organic material is heated in a crucible placed in a vacuum chamber to sublimate or vaporize the organic material to form a film on the substrate. Some of the more active materials, such as Li, react with the air during the opening of the package, resulting in contamination of the active material.

### SUMMARY OF THE DISCLOSURE

The technical problem to be solved by the present disclosure is to overcome the deficiencies of the prior art and to provide a sealed storage device and a heating assembly with a simple structure and capable of avoiding exposure of the active material to the atmosphere.

In order to achieve the above object, the present disclosure adopts the following technical solutions.

A storage device with a sealing function, including a storage box, a sealing cover, and an elastic member, the storage box is provided with an opening, the sealing cover is rotatably connected to the storage box, the sealing cover is used to seal the opening, the fixing end of the elastic member is connected to the storage box, the free end of the elastic member is configured to connect the sealing cover so that the sealing cover opens from the opening.

Optionally, the sealing cover includes a cover and a sealing ring provided on a surface of the cover facing the opening, the sealing ring is configured to fit the periphery of the opening, the cover is rotatably connected to an outer surface of the storage box, and the free end of the elastic member is configured to connect the cover.

Optionally, the cover further includes a connecting portion, the connecting portion is disposed on the surface of the cover facing away from the opening, and the free end of the elastic member is used to connect the connecting portion.

Optionally, the storage device with a sealing function further includes a rotating shaft rotatably disposed on the outer surface of the storage box, wherein the rotating shaft is located on the same plane as the opening, and one end of the cover is fixed on the rotating shaft.

Optionally, the connecting portion is located on the side of the cover away from the rotating shaft.

Optionally, the storage box further includes a fixing portion, the fixing portion and the opening are located on the same outer surface of the storage box, and the fixing end of the elastic member is connected to the fixing portion.

Optionally, the elastic member is a spring.

Optionally, the materials of the storage box, the sealing cover and the elastic member are all high temperature resistant materials, and the high temperature resistant range of the high temperature resistant material is from 500° C. to 1000° C.

The disclosure also discloses a heating assembly, which includes a crucible and any one of the above storage devices with a sealing function, wherein the storage device with a sealing function is accommodated in the crucible.

Optionally, the crucible includes a crucible with a feed inlet and a crucible cover covered on the feed inlet of the crucible, the crucible cover is provided with a through hole, the storage box is disposed in the crucible, and the opening is directly opposite to the through hole.

The present disclosure discloses a sealed storage device and a heating assembly, the sealing cover is used to seal the opening of the storage box so as to prevent the active material in the storage box from being exposed to the air and the sealing cover is connected by the elastic member so as to open the sealing cover which is tightly adhered to the opening.

### BRIEF DESCRIPTION OF THE DRAWINGS

FIG. 1 is a sectional diagram of the storage device according to the embodiment of the present disclosure.

FIG. 2 is another cross-sectional diagram of the storage device according to the embodiment of the present disclosure.

FIG. 3 is a cross-sectional diagram of the heating assembly according to the embodiment of the present disclosure.

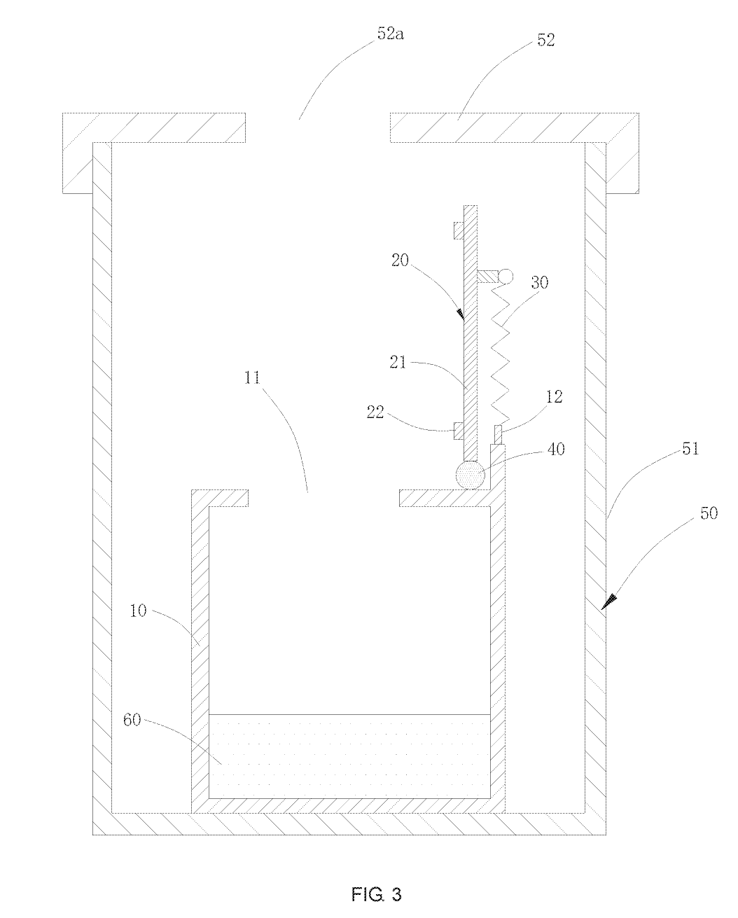

### DETAILED DESCRIPTION OF PREFERRED EMBODIMENTS

In order to make the objectives, technical solutions and advantages of the present disclosure more comprehensible, the present disclosure is further described in detail below with reference to the accompanying drawings and embodiments. It should be understood that the specific embodiments described herein are merely used to explain the present disclosure, and are not intended to limit the present disclosure.

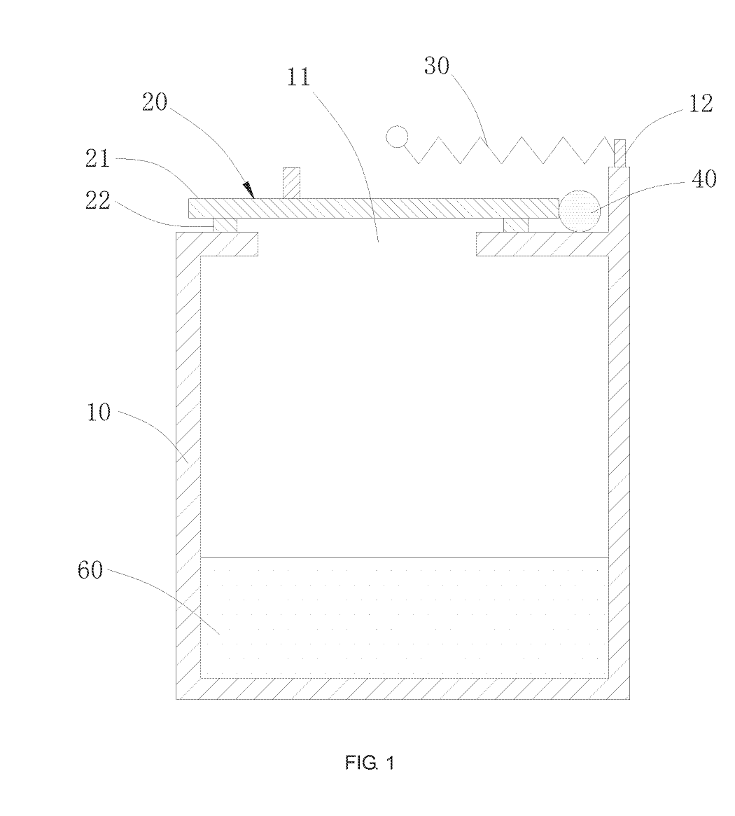

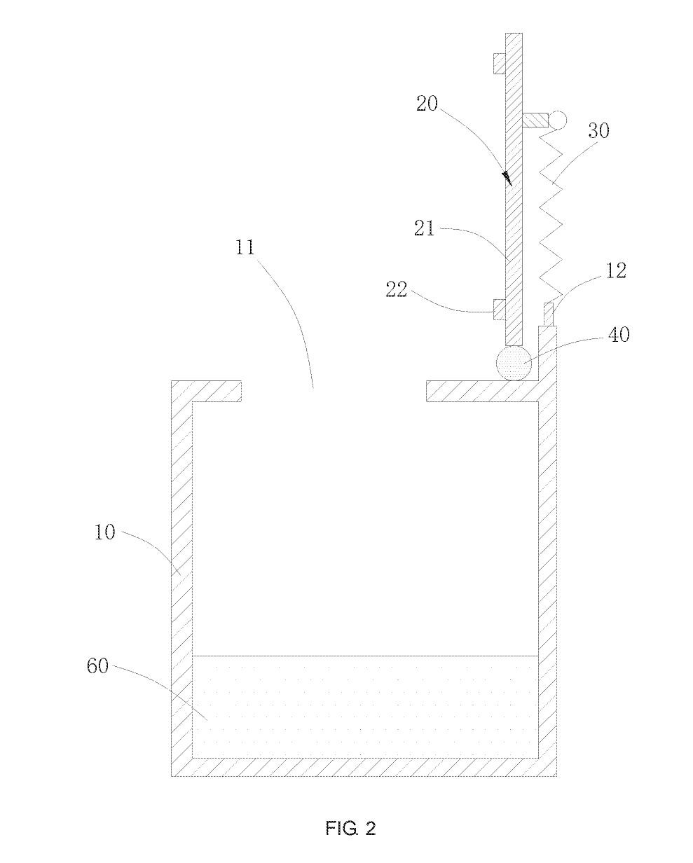

As shown in FIG. 1 and FIG. 2, the storage device with a sealing function of the present embodiment includes a storage box 10, a sealing cover 20 and an elastic member 30. Wherein, the storage box 10 is provided with an opening 11, the sealing cover 20 is rotatably connected to the storage box 10, the sealing cover 20 is used for sealing the opening 11 of the storage box 10. The fixing end of the elastic member 30 is connected to the storage box 10. The free end of the elastic member 30 is used for connecting the sealing cover 20. In this way, the opening 11 can be sealed by the sealing cover 20 to prevent the active material 60 in the storage box 10 from being exposed to the air and reacting with the air. In addition, the sealing cover 20 attached to the opening 11 can be opened by the elastic pulling force of the elastic member 30, the active material 60 in the box has been released, and the active material 60 has been added into the box.

As a preferred embodiment, the sealing cover 20 includes a cover 21 and a sealing ring 22 provided on the surface of the cover 21 facing the opening 11, the sealing ring 22 is used to fit the periphery of the opening 11. The area of the cover 21 is larger than the area of the opening 11. The shape of the sealing ring 22 matches the shape of the opening 11. The cover 21 is rotatably connected to the outer surface of the storage box 10. The free end of the elastic member 30 is used to connect the cover 21. Specifically, during use, the cover 21 is covered on the opening 11 to vacuumize the storage box 10, the sealing ring 22 is closely attached to the periphery of the opening 11 by utilizing the pressure of the atmospheric pressure to seal the active material 60. When the sealing cover 20 needs to be opened, the free end of the elastic member 30 is first connected to the cover 21, and then the storage box 10 is placed in the vacuum chamber, when the air pressure difference inside and outside the storage box 10 is reduced to a certain degree, the sealing cover 20 is opened by the elastic pulling force of the elastic member 30.

Of course, in other embodiments, when the cover 21 is covered on the opening 11, the sealing ring 22 is adhered to the periphery of the opening 11 by glue to seal the active material 60. When the sealing cover 20 needs to be opened, the free end of the elastic member 30 is first connected to the cover 21, the sealing cover 20 is opened under the elastic pulling force of the elastic member 30, the elastic tensile force of the elastic member 30 is greater than the adhesive tension of the glue.

Further, the cover 21 further includes a connecting portion 21a, The connecting portion 21a is disposed on the surface of the cover 21 facing away from the opening 11. The free end of the elastic member 30 is for connecting with the connecting portion 21a for conveniently opening the cover 21. The connecting portion 21a is annular in shape, so that the free end of the elastic member 30 is connected to the connecting portion 21a. Of course, in other embodiments, the connecting portion 21a can also be hooked to facilitate the connecting portion 21a directly connected to the free end of the elastic member 30.

As a preferred embodiment, the storage device with a sealing function further includes a rotating shaft 40 rotatably disposed on the outer surface of the storage box 10, and the rotating shaft 40 is located on the same plane as the opening 11. One end of the cover 21 is fixed on the rotating shaft 40. Further, the connecting portion 21a is located on the side of the cover 21 far away from the rotating shaft 41, so that the pulling force between the elastic member 30 and the cover 21 increases to facilitate opening the sealing cover.

Further, the storage box 10 further includes a fixing portion 12, the fixing portion 12 and the opening 11 are located on the same outer surface of the storage box 10, the fixing end of the elastic member 30 is connected to the fixing portion 12, wherein the fixing portion 12 extends in a direction parallel to the opening 11 so as to ensure a certain distance between the elastic member 30 and the connecting portion 21a so as to facilitate pulling the cover 21.

As a preferred embodiment, the elastic member 30 is selected as a spring, the spring is light in weight, and the connecting and disassembling of the cover 21 is facilitated. Further, the materials of the storage box 10, the sealing cover 20 and the elastic member 30 are all high temperature resistant materials, and the high temperature resistant materials have a high temperature resistant range of 500° C. to 1000° C. One of the high temperature materials can choose high temperature metal materials, such as copper. In this way, when the active material needs to be heated at a high temperature, the sealing cover 20 is opened and the storage device is placed in a heating environment. The high temperature does not affect the storage box 10, the sealing cover 20 and the elastic member 30.

The embodiment of the present disclosure further provides a heating assembly, including a crucible 50 and the above-mentioned storage device with a sealing function, the storage device with a sealing function is disposed in the crucible 50, and the active material 60 in the storage box 10 is heated by heating the crucible 50.

Further, the crucible 50 includes a crucible 51 with a feed inlet and a crucible cover 52 capped on the feed inlet of the crucible 51, the crucible cover 52 is provided with a through hole 52a, the storage box 10 is disposed in the crucible 51, and the opening 11 is directly opposite to the through hole 52a. In specific use, the free end of the elastic member is connected to the connecting portion 21a of the cover 21, the storage device is placed in the crucible 51, the crucible 50 is placed in the vacuum chamber and evacuated, when the pressure difference inside and outside the storage box 10 is reduced to a certain extent, the elastic member 30 opens the sealing cover 20 by the elastic pulling force, after the sealing cover 20 is opened, the pressure inside the vacuum chamber has dropped to a relatively low level and the degree of reaction of the active material with the air is greatly reduced. The present embodiment provides a heating assembly which can be applied to the production process of vacuum evaporation of an organic light emitting diode panel to ensure the purity of the active material so as to improve the production efficiency and ensure the panel quality.

The present disclosure discloses a storage device with a sealing function and a heating assembly, the sealing cover is used to seal the opening of the storage box so as to prevent the active material in the storage box from being exposed to the air and the sealing cover is connected by the elastic member so as to open the sealing cover which is tightly adhered to the opening.

While specific embodiments of the present disclosure have been described in detail, some embodiments have been shown and described. It will be understood by those skilled in the art that, these embodiments may be modified and improved without departing from the spirit and scope of the present disclosure as defined by the claims and their equivalents, and such modifications and improvements should also fall within the protection scope of the present disclosure.

What is claimed is:

1. A storage device with a sealing function, comprising a storage box, a sealing cover, and an elastic member, wherein the storage box is provided with an opening, the sealing cover is rotatably connected to the storage box, the sealing cover is configured to seal the opening, a fixing end of the elastic member is connected to the storage box, a free end of the elastic member is configured to connect the sealing cover so that the sealing cover opens from the opening.

2. The storage device with a sealing function according to claim 1, wherein the sealing cover comprises a cover and a sealing ring provided on a surface of the cover facing the opening, the sealing ring is configured to fit the periphery of the opening, the cover is rotatably connected to an outer surface of the storage box, and the free end of the elastic member is configured to connect the cover.

3. The storage device with a sealing function according to claim 2, wherein the cover further comprises a connecting portion, the connecting portion is disposed on a surface of the cover facing away from the opening, and the free end of the elastic member is configured to connect the connecting portion.

4. The storage device with a sealing function according to claim 3, wherein the storage device with a sealing function further comprises a rotating shaft rotatably disposed on the outer surface of the storage box, wherein the rotating shaft is located on the same plane as the opening, and one end of the cover is fixed on the rotating shaft.

5. The storage device with a sealing function according to claim 3, wherein the connecting portion is located on a side of the cover away from the rotating shaft.

6. The storage device with a sealing function according to claim 3, wherein the storage box further comprises a fixing portion, the fixing portion and the opening are located on the same outer surface of the storage box, and a fixing end of the elastic member is connected to the fixing portion.

7. The storage device with a sealing function according to claim 1, wherein the elastic member is a spring.

8. The storage device with a sealing function according to claim 1, wherein materials of the storage box, the sealing cover and the elastic member are all high temperature resistant materials, and a high temperature resistant range of the high temperature resistant material is from 500° C. to 1000° C.

9. A heating assembly, comprising a crucible and a storage device with a sealing function, wherein the storage device with a sealing function is accommodated in the crucible; the storage device with a sealing function comprising a storage box, a sealing cover, and an elastic member, the storage box is provided with an opening, the sealing cover is rotatably connected to the storage box, the sealing cover is configured to seal the opening, a fixing end of the elastic member is connected to the storage box, a free end of the elastic member is configured to connect the sealing cover so that the sealing cover opens from the opening.

10. The storage device with a sealing function according to claim 9, wherein the sealing cover comprises a cover and a sealing ring provided on a surface of the cover facing the opening, the sealing ring is configured to fit the periphery of the opening, the cover is rotatably connected to an outer surface of the storage box, and the free end of the elastic member is configured to connect the cover.

11. The storage device with a sealing function according to claim 10, wherein the cover further comprises a connecting portion, the connecting portion is disposed on a surface of the cover facing away from the opening, and the free end of the elastic member is configured to connect the connecting portion.

12. The storage device with a sealing function according to claim 11, wherein the storage device with a sealing function further comprises a rotating shaft rotatably disposed on the outer surface of the storage box, wherein the rotating shaft is located on the same plane as the opening, and one end of the cover is fixed on the rotating shaft.

13. The storage device with a sealing function according to claim 11, wherein the connecting portion is located on a side of the cover away from the rotating shaft.

14. The storage device with a sealing function according to claim 11, wherein the storage box further comprises a fixing portion, the fixing portion and the opening are located on the same outer surface of the storage box, and a fixing end of the elastic member is connected to the fixing portion.

15. The storage device with a sealing function according to claim 9, wherein the elastic member is a spring.

16. The storage device with a sealing function according to claim 9, wherein materials of the storage box, the sealing cover and the elastic member are all high temperature resistant materials, and a high temperature resistant range of the high temperature resistant material is from 500° C. to 1000° C.

17. The heating assembly according to claim 9, wherein the crucible comprises a crucible with a feed inlet and a crucible cover covered on the feed inlet of the crucible, the crucible cover is provided with a through hole, the storage box is disposed in the crucible, and the opening is directly opposite to the through hole.
